(19) United States
(12) Patent Application Publication
(10) Pub. No.: US 2011/0032464 A1
(43) Pub. Date: Feb. 10, 2011

(54) LIQUID CRYSTAL DISPLAY AND MANUFACTURING METHOD FOR THE SAME

(75) Inventors: Gyo-Jic SHIN, Hwaseong-si (KR); Hyun-ku Ahn, Hwaseong-si (KR); Baek-Kyun Jeon, Yongin-si (KR); Hoi-Lim Kim, Eujeongbu-si (KR); Jeong-Hye Choi, Incheon-si (KR); Yong-Hwan Shin, Yongin-si (KR); Min-Sik Jung, Seoul (KR)

Correspondence Address: H.C. PARK & ASSOCIATES, PLC, 8500 LEESBURG PIKE, SUITE 7500, VIENNA, VA, 22182, US

(73) Assignee: Samsung Electronics Co., Ltd., Suwon-si (KR)

(21) Appl. No.: 12/845,289

(22) Filed: Jul. 28, 2010

(30) Foreign Application Priority Data
Aug. 6, 2009 (KR) 10-2009-0072517

(51) Int. Cl. G02F 1/1337; G02F 1/1333; G03F 7/20

(52) U.S. Cl. 349/123; 349/158; 430/312; 349/187

(57) ABSTRACT

A liquid crystal display according to an exemplary embodiment of the present invention includes a first substrate and a second substrate facing each other and a liquid crystal layer formed between the first substrate and the second substrate and including liquid crystal molecules. The liquid crystal layer includes a first sub-region and a second sub-region having different alignment azimuth angles of the liquid crystal molecules, the liquid crystal molecules of the first sub-region are aligned to have a first azimuth angle and a polar angle of less than 90° near the first substrate and are vertically aligned near the second substrate, and the liquid crystal molecules of the second sub-region are aligned to have a second azimuth angle and a polar angle of less than 90° near the second substrate and are vertically aligned near the first substrate.

### CROSS REFERENCE TO RELATED APPLICATION

This application claims priority from and the benefit of Korean Patent Application No. 10-2009-0072517, filed on Aug. 6, 2009, which is hereby incorporated by reference for all purposes as if fully set forth herein.

### BACKGROUND OF THE INVENTION

1. Field of the Invention

Exemplary embodiments of the present invention relate to a liquid crystal display and a manufacturing method thereof.

2. Discussion of the Background

Liquid crystal displays are now widely used as one type of flat panel display. A liquid crystal display has two display panels on which field generating electrodes such as pixel is electrodes and a common electrode are formed, and a liquid crystal layer interposed between the panels. In the liquid crystal display, voltages are applied to the field generating electrodes to generate an electric field over the liquid crystal layer, and the alignment of liquid crystal molecules of the liquid crystal layer is determined by the electric field. Accordingly, the polarization of incident light is controlled by the alignment of the liquid crystal molecules, thereby performing image display.

Among the liquid crystal displays, a vertical alignment (VA) mode liquid crystal display, which aligns liquid crystal molecules such that their long axes are perpendicular to the panels in the absence of an electric field, is of interest to develop.

In the VA mode liquid crystal display, a wide viewing angle can be realized by cutouts such as minute slits in the field-generating electrodes and protrusions on the field-generating electrodes. Since the cutouts and protrusions can determine the tilt directions of the liquid crystal molecules, the tilt directions can be distributed severally by using the cutouts and protrusions such that the reference viewing angle is widened. However, the cutouts and the protrusions may reduce the aperture ratio of the liquid crystal display.

Also, a method for providing a pretilt to the liquid crystal molecules in the absence of an electric field is of interest to develop to improve the response speed of the liquid crystal display while dispersing the inclination direction of the liquid crystal molecules in the various directions. For the liquid crystal molecules to have the pretilt of the various directions, alignment layers having the various alignment directions may be used, or a thermal- or light-hardenable material may be added to the liquid crystal layer. The liquid crystal layer with the added thermal- or light-hardenable material is applied with an electric field, and then exposed to heat or light to cure the hardenable material to maintain the slope of the LC molecules in predetermined directions when the electric field is removed.

In a light-alignment method in which a thermal- or light-hardenable material is added to the liquid crystal layer or to an alignment layer and light is irradiated to cure the light-hardenable material to slope the liquid crystal molecules in predetermined directions, the upper substrate and the lower substrate may be aligned differently from each other, for example in a crossing direction, and then combined. Thereby the liquid crystal molecules are inclined in the direction of a vector combination of the alignment directions of the upper substrate and the lower substrate.

In a case in which the upper substrate and the lower substrate are aligned differently from each other, when one substrate of the upper substrate and the lower substrate is not aligned in the desired direction or the alignment region is out of the desired position such that misalignment occurs, the transmittance of the liquid crystal display may be reduced. Also, since the upper substrate and the lower substrate are entirely light-aligned, many impurities may be generated during the light-alignment such that the light energy used for the light-alignment is increased.

The above information disclosed in this Background section is only for enhancement of understanding of the background of the invention and therefore it may contain information that is not part of the prior art at the time of the invention.

### SUMMARY OF THE INVENTION

Exemplary embodiments of the present invention provide a liquid crystal display having an inclination direction of liquid crystal molecules dispersed in various directions and an increased response speed of the liquid crystal layer by easily aligning the liquid crystal molecules in the various directions.

Additional features of the invention will be set forth in the description which follows, and in part will be apparent from the description, or may be learned by practice of the invention.

An exemplary embodiment of the present invention discloses a liquid crystal display that includes a first substrate and a second substrate facing each other, and a liquid crystal layer formed between the first substrate and the second substrate and including liquid crystal molecules. The liquid crystal layer includes a first sub-region and a second sub-region having different alignment azimuth angles of the liquid crystal molecules, the liquid crystal molecules of the first sub-region are aligned to have a first azimuth angle and a polar angle of less than 90° near the first substrate and are vertically aligned near the second substrate. The liquid crystal molecules of the second sub-region are aligned to have a second azimuth angle and a polar angle of less than 90° near the second substrate and are vertically aligned near the first substrate.

An exemplary embodiment of the present invention also discloses a manufacturing method of a liquid crystal display that includes disposing a first mask including a first transmission region and a first light blocking region on a first alignment layer disposed on a first substrate, irradiating ultraviolet rays to the first alignment layer through the first mask to align the first alignment layer corresponding to the first transmission region in a first direction. The method includes disposing a second mask including a second transmission region corresponding to the first light blocking region and a second light blocking region corresponding to the first transmission region on a second alignment layer disposed on a second substrate, irradiating ultraviolet rays to the second alignment layer through the second mask to align the second alignment layer corresponding to the second transmission region in a second direction. The method also includes combining the first substrate and the second substrate to correspond the first transmission region to the second light blocking region and the first light blocking region to the second transmission region.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1A is a schematic layout view of a pixel of a liquid crystal display according to an exemplary embodiment of the present invention.

FIG. 1B is a schematic cross-sectional view of a pixel of a liquid crystal display according to an exemplary embodiment of the present invention.

FIG. 1C is a layout view of an example of a pixel electrode in a pixel of a liquid crystal display according to an exemplary embodiment of the present invention.

FIG. 2 is a flowchart for explaining a manufacturing sequence of a liquid crystal cell for a liquid crystal display according to an exemplary embodiment of the present invention.

FIG. 3, FIG. 4, FIG. 5, FIG. 6, FIG. 7, FIG. 8, FIG. 9, and FIG. 10 are layout views of a mask used for a light-alignment method and a pixel light-aligned among a is manufacturing method of a liquid crystal display according to an exemplary embodiment of the present invention.

FIG. 11 is a graph showing a curved line of a voltage-transmittance according to an experimental example of the present invention.

### DETAILED DESCRIPTION OF THE ILLUSTRATED EMBODIMENTS

The invention is described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art.

In the drawings, the thickness of layers, films, panels, regions, etc., may be exaggerated for clarity. Like reference numerals in the drawings designate like elements throughout the specification. It will be understood that when an element such as a layer, film, region, or substrate is referred to as being “on” or “connected to” another element, it can be directly on or directly connected to the other element, or intervening elements may be present. In contrast, when an element is referred to as being “directly on” or “directly connected to” another element, there are no intervening elements present.

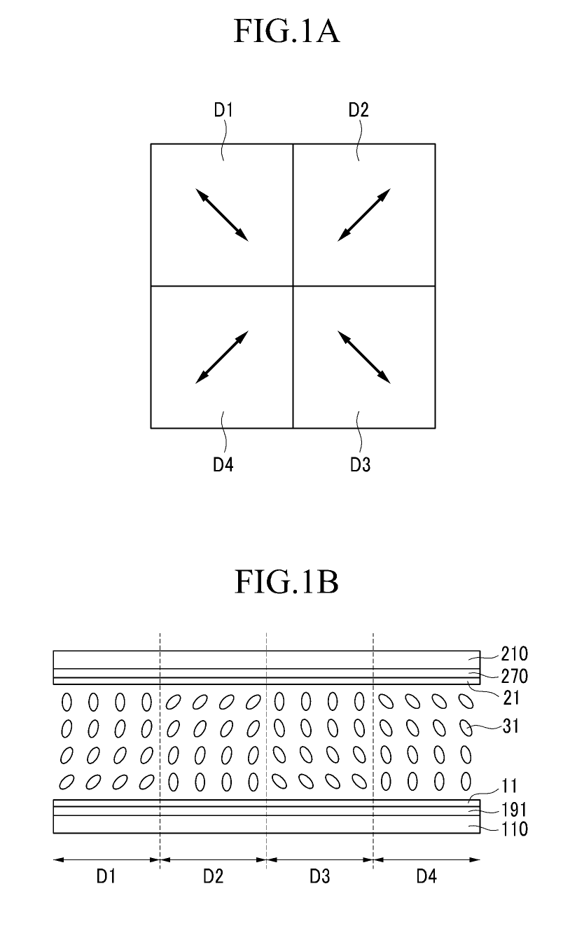

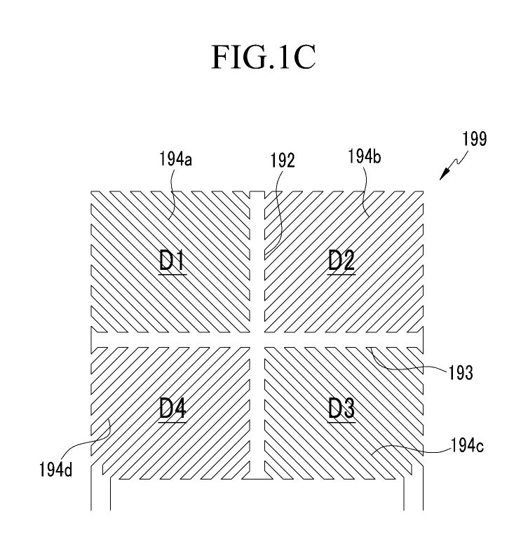

Now, a structure of a pixel of a liquid crystal display according to an exemplary embodiment of the present invention will be described with reference to FIG. 1A, FIG. 1B, and FIG. 1C. FIG. 1A is a schematic layout view of a pixel of a liquid crystal display according to an exemplary embodiment of the present invention, FIG. 1B is a schematic cross-sectional view of a pixel of a liquid crystal display according to an exemplary embodiment of the present invention, and FIG. 1C is a layout view of an example of a pixel electrode in a pixel of a liquid crystal display according to an exemplary embodiment of the present invention.

Referring to FIG. 1A, a pixel of a liquid crystal display according to an exemplary embodiment of the present invention includes a first domain D1, a second domain D2, a third domain D3, and a fourth domain D4 neighboring each other and including liquid crystal molecules having different pretilts. The liquid crystal molecules of each domain D1, D2, D3, and D4 are inclined to have a pretilt in a state in which an electric field is not applied, and an example of the direction of a liquid crystal director of the liquid crystal molecules, that is, the pretilted azimuth angle, is represented by arrows in FIG. 1A. As shown in the example, the direction of the liquid crystal molecules that are pretilted in the horizontal direction in the domains D1, D2, D3, and D4, that is, the azimuth angle, is about 45° or 135° with respect to the boundary of each pixel. However, in the pixel of the liquid crystal display according to another exemplary embodiment of the present invention, the azimuth angle of the liquid crystal molecules that are pretilted in the domains D1, D2, D3, and D4 may be parallel to the boundary of the pixel. The liquid crystal molecules are inclined in the pretilt direction, and the inclination direction of the liquid crystal molecules is verified according to the region in one pixel such that the reference viewing angle of the liquid crystal display is increased, and the response speed of the liquid crystal molecules may be improved.

Referring to FIG. 1B, a liquid crystal display according to an exemplary embodiment of the present invention includes a lower substrate 110, a pixel electrode 191 formed on the lower substrate 110, a lower alignment layer 11 formed on the pixel electrode 191, an upper substrate 210 facing the lower substrate 110, a common electrode 270 formed on the upper substrate 210, an upper alignment layer 21 formed on the common electrode 270, and a is liquid crystal layer disposed between the lower substrate 110 and the upper substrate 210 and including a plurality of liquid crystal molecules 31. Although not shown, a polarizer may be disposed below the lower substrate 110 and another polarizer may be disposed above the upper substrate 210.

As shown in FIG. 1B, the liquid crystal molecules 31 of the first domain D1 that have the azimuth angle of the first direction near the lower alignment layer 11, are pretilted to have a polar angle of less than 90° with respect to the surface of the lower substrate 110, and are vertically aligned near the upper alignment layer 21, and the liquid crystal molecules 31 of the second domain D2 are vertically aligned near the lower alignment layer 11, have the azimuth angle of the second direction near the upper alignment layer 21, and are pretilted to have the polar angle of less than 90° with respect to the surface of the upper substrate 210. Accordingly, when the liquid crystal molecules 31 are applied with an electric field, they are inclined on average in the first direction in the first domain D1, and are inclined on average in the second direction in the second domain D2.

Also, the liquid crystal molecules 31 of the third domain D3 have the azimuth angle of the third direction near the lower alignment layer 11, are pretilted to have a polar angle of less than 90° with respect to the surface of the lower substrate 110, and are vertically aligned near the upper alignment layer 21, and the liquid crystal molecules 31 of the fourth domain D4 are vertically aligned near the lower alignment layer 11, have the azimuth angle of the fourth direction near the upper alignment layer 21, and are pretilted to have the polar angle of less than 90° with respect to the surface of the upper substrate 210. Accordingly, when the liquid crystal molecules 31 are applied with the electric field, they are inclined on average in the third direction in the third domain D3, and are inclined on average in the fourth direction in the fourth domain D4.

Here, the first direction and the third direction may be opposite to each other, and for example, may respectively form an angle of about 45° and about 135° with respect to the boundary of the pixel, and the second direction and the fourth direction may be opposite to each other, and for example, may respectively form an angle of about 45° and about 135° with respect to the boundary of the pixel. Also, the first direction and the third direction may be parallel to each other, and the second direction and the fourth direction may be parallel to each other.

Further, the pixel electrode 191 of the liquid crystal display according to an exemplary embodiment of the present invention may include a basic electrode 199 as shown in FIG. 1C or a modification thereof. As shown in FIG. 1C, the overall shape of the basic electrode 199 is a quadrangle, and includes a cross-shaped stem including a transverse stem 193 and a longitudinal stem 192 that are crossed. Also, the basic electrode 199 including the first domain D1, the second domain D2, the third domain D3, and the fourth domain D4 may be divided by the transverse stem 193 and the longitudinal stem 192, and each of the domains D1, D2, D3, and D4 includes a plurality of first, second, third, and fourth minute branches 194a, 194b, 194c, and 194d.

The first minute branches 194a obliquely extend from the transverse stem 193 or the longitudinal stem 192 in the upper-left direction, and the second minute branches 194b obliquely extend from the transverse stem 193 or the longitudinal stem 192 in the upper-right direction. The third minute branches 194c obliquely extend from the transverse stem 193 or the longitudinal stem 192 in the lower-left direction, and the fourth minute branches 194d obliquely extend from the transverse stem 193 or the longitudinal stem 192 in the lower-right direction.

The first, second, third, and fourth minute branches 194a, 194b, 194c, and 194d form an angle of about 45 degrees or 135 degrees with the transverse stem 193. Also, the minute branches 194a, 194b, 194c, and 194d of two neighboring sub-regions D1, D2, D3, and D4 may be crossed.

The length direction of each of the minute branches 194a, 194b, 194c, and 194d of each domain D1, D2, D3, and D4 is respectively parallel to the first direction, the second direction, the third direction, and the fourth direction in which the liquid crystal molecules 31 are pretilted in the domains D1, D2, D3, and D4.

The pixel electrodes 191 applied with the pixel voltage and the common electrode 270 applied with the common voltage form an electric field over the liquid crystal layer. Thus, the liquid crystal molecules 31 of the liquid crystal layer change directions so that the major axes thereof become perpendicular to the direction of the electric field in response to the electric field. The degree of change of the polarization of the light that is incident to the liquid crystal layer is according to the inclination degree of the liquid crystal molecules, and this change of the polarization appears as a change of transmittance by the other polarizer, thereby displaying images of the liquid crystal display.

On the other hand, the edges of the minute branches 194a, 194b, 194c, and 194d distort the electric field to make the horizontal components perpendicular to the edges of the minute branches 194a, 194b, 194c, and 194d, and the inclination direction of the liquid crystal molecules 31 is determined in the direction determined by the horizontal components. Also, as described above, the liquid crystal molecules 31 of the present invention are already pretilted in the direction parallel to the length direction of the minute branches 194a, 194b, 194c, and 194d such that they are tilted in the required direction one time, thereby the response speed of the liquid crystal display may be improved.

In FIG. 1C, the basic electrode 199 of the pixel electrode 191 has the minute branches 194a, 194b, 194c, and 194d in the domains D1, D2, D3, and D4, however in the case of the domains D1 and D3 that are light-aligned near the lower alignment layer 11, the pixel electrode 191 may have a general square shape, not the shape of the minute branches 194a and 194c.

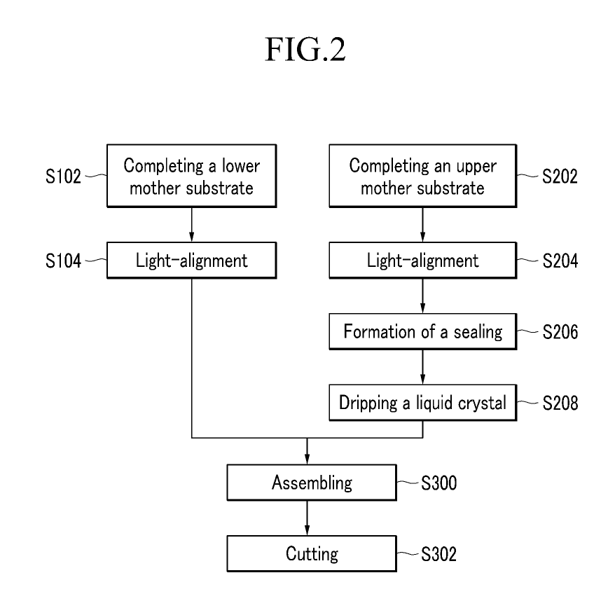

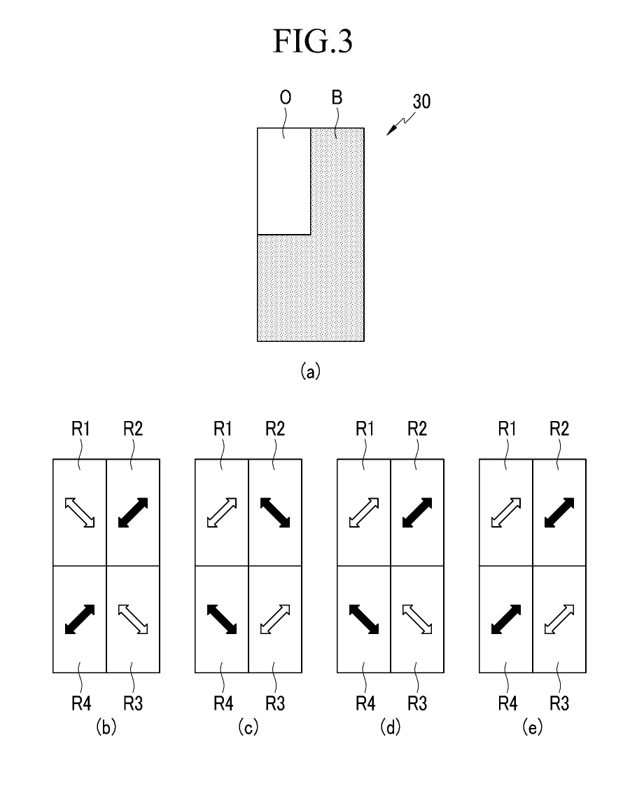

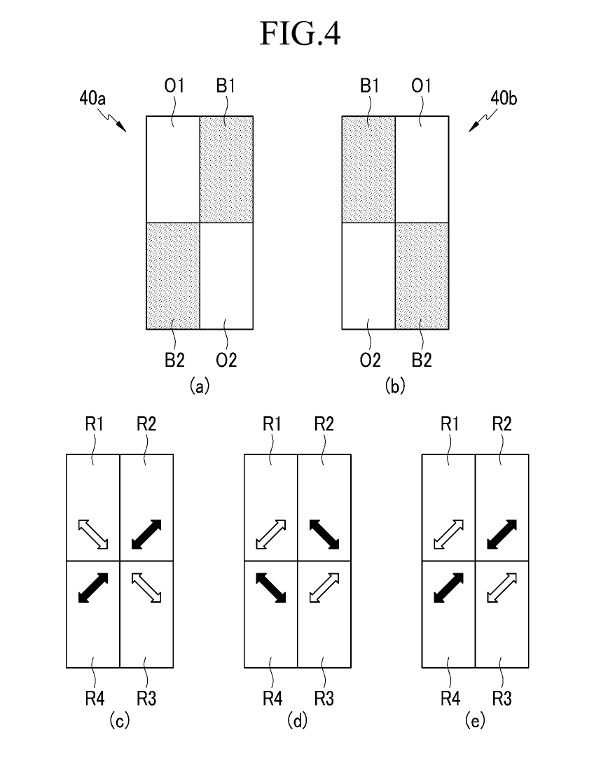

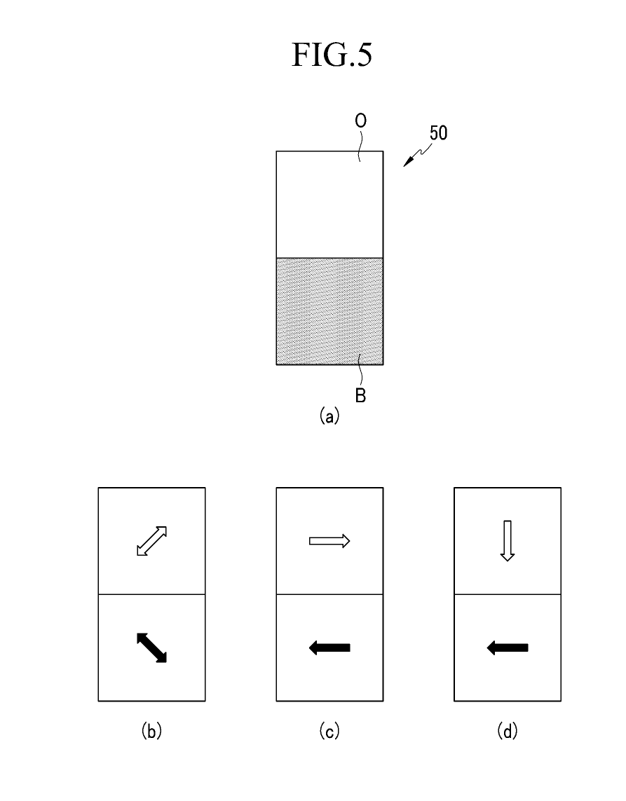

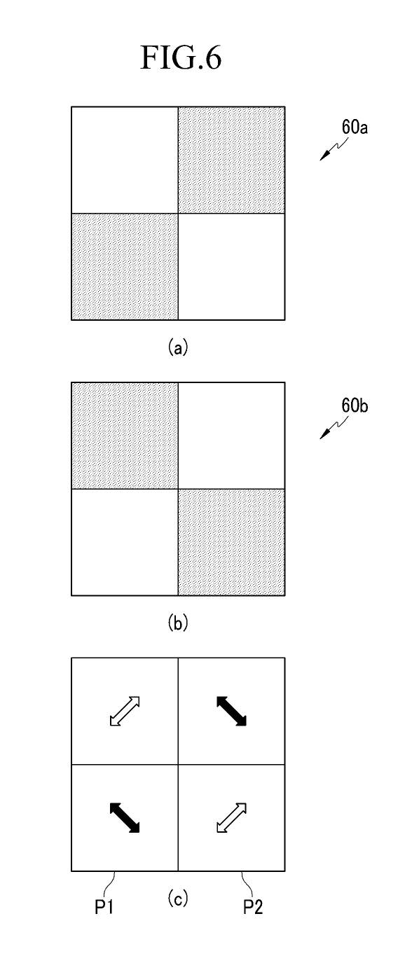

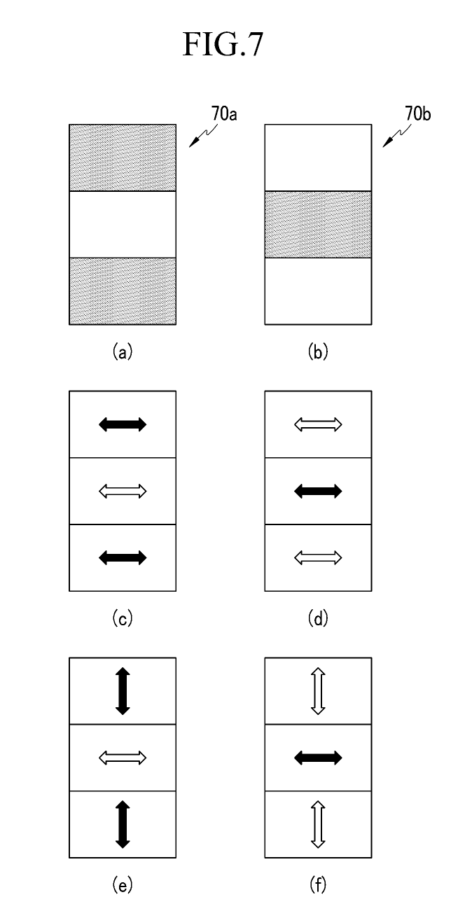

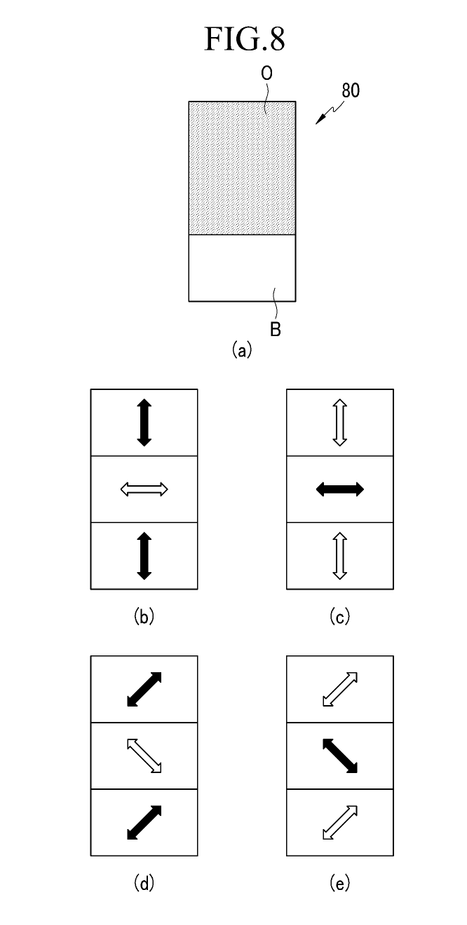

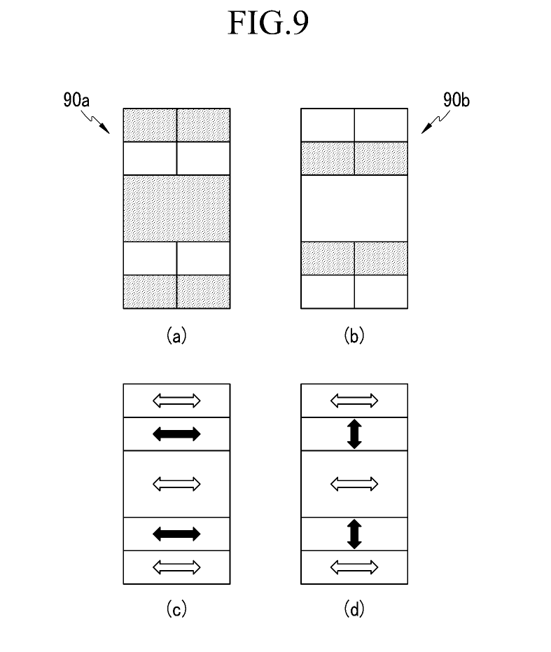

Next, a manufacturing method of a liquid crystal display according to an exemplary embodiment of the present invention will be described with reference to FIG. 2, FIG. 3, FIG. 4, FIG. 5, FIG. 6, FIG. 7, FIG. 8, FIG. 9, and FIG. 10. FIG. 2 is a flowchart for explaining a manufacturing sequence of a liquid crystal cell for a liquid crystal display according to an exemplary embodiment of the present invention, and FIG. 3, FIG. 4, FIG. 5, FIG. 6, FIG. 7, FIG. 8, FIG. 9, and FIG. 10 are layout views of a mask used for a light-alignment method and a pixel light-aligned in a manufacturing method of a liquid crystal display according to an exemplary embodiment of the present invention.

Firstly, as shown in FIG. 2, an upper mother substrate and a lower mother substrate are completed through each process (S102 and S202). The upper mother substrate includes a common electrode, and may further include a color filter. The lower mother substrate may include a thin film transistor and a pixel electrode.

Alignment layers formed in the upper mother substrate and the lower mother substrate are irradiated with linearly polarized ultraviolet (LPUV) rays or are partially polarized for light alignment (S104 and S204). The linearly polarized ultraviolet rays are obliquely irradiated to the surface of the alignment layer to generate the same effect as that of the alignment layer surface being rubbed in a predetermined direction. The method in which the linearly polarized ultraviolet rays are obliquely irradiated to the surface of the alignment layer is is possible by inclining the mother substrate or by inclining an irradiation. Here, if a light-polymerizing material is used, a light stabilizing agent and/or a cross-linking agent may be added.

Next, a sealing is formed (S206) on the upper mother substrate and a liquid crystal is dripped thereto (S208), and the lower mother substrate and the upper mother substrate are combined (S300).

Next, they are scribed according to a cutting line to divide the liquid crystal display assembly into respective liquid crystal cells (S302).

When the liquid crystal is filled by liquid crystal injection, the liquid crystal is injected after dividing the liquid crystal cells.

Now, a light-alignment method of a manufacturing method of a liquid crystal display according to an exemplary embodiment of the present invention will be described with reference to FIG. 3, FIG. 4, FIG. 5, FIG. 6, FIG. 7, FIG. 8, FIG. 9, and FIG. 10.

Referring to FIG. 3, in a light-alignment method of the liquid crystal display according to the present exemplary embodiment, the lower substrate is exposed by using a slit mask 30 including an opening O exposing one of a plurality of domains of one pixel and a light blocking portion B corresponding to the rest of the pixel, as shown in FIG. 3(a). Here, a mask 30 corresponding to one pixel is shown in FIG. 3(a), however a wider region may be simultaneously light-aligned by using a large mask with appropriate openings O repeatedly disposed as one unit (not shown), and the mother substrate may be simultaneously light-aligned by a similar large mask.

The linearly polarized ultraviolet rays are irradiated by using the mask 30 shown in FIG. 3(a) such that the first region of the upper substrate is light-aligned. Next, after rotating is the mask 30 by 180°, the linearly polarized ultraviolet rays are irradiated such that the third region of the upper substrate is light-aligned. Here, the azimuth angle that is aligned by controlling the irradiation direction of the ultraviolet rays and exposing two times or more may be controlled to the desired angle. For example, after irradiating the linearly polarized ultraviolet rays in the right and left directions of the mask, the linearly polarized ultraviolet rays are irradiated in the up and down directions of the mask, or the linearly polarized ultraviolet rays are irradiated in a reverse sequence for the azimuth angle of the liquid crystal director to be toward the right and down directions of the mask.

Next, after using the mask that has right and left symmetry with respect to the mask 30 shown in FIG. 3(a), or reversing the mask 30 up and down, the linearly polarized ultraviolet rays are irradiated such that the second region of the lower substrate is light-aligned, and after rotating the mask 30 by 180°, the fourth region of the lower substrate is light-aligned by irradiating the linearly polarized ultraviolet rays.

As described above, examples in which the light-aligned lower substrate and the light-aligned upper substrate are combined are shown in FIG. 3(b), FIG. 3(c), FIG. 3(d), and FIG. 3(e). In FIG. 3(b), FIG. 3(c), FIG. 3(d), and FIG. 3(e), the directions that the liquid crystal directors are directed in the sub-regions R1, R2, R3, and R4 of the pixel are represented by arrows, wherein the case in which the lower substrate is aligned is represented as the solid arrow, and the case in which the upper substrate is aligned is represented as the open lined arrow.

Referring to FIG. 3(b), the upper substrate is light-aligned to have the pretilt, the lower substrate is vertically aligned, and the azimuth angle of the pretilt is aligned to be directed toward the right and down directions from the left and up directions of the pixel, or is aligned to be directed toward the left and up directions from the right and down directions of the pixel in the first sub-region R1, and the upper substrate is vertically aligned, the lower substrate is light-aligned to have the pretilt. The upper substrate is vertically aligned, the lower substrate is light-aligned to have the pretilt, and the azimuth angle of the pretilt is aligned to be directed toward the left and down directions from the right and up directions of the pixel, or is aligned to be directed from the left and down directions toward the right and up directions of the pixel in the second sub-region R2. In the third sub-region R3, the upper substrate is light-aligned to have the pretilt, the lower substrate is vertically aligned, the azimuth angle of the pretilt is aligned to be directed from the right and down directions to the left and up directions of the pixel, or is aligned to be directed from the left and up directions toward the right and down directions of the pixel. In the fourth sub-region R4, the upper substrate is vertically aligned, the lower substrate is light-aligned to have the pretilt, and the azimuth angle of the pretilt is aligned to be directed from the left and down directions to the right and up directions of the pixel, or is aligned to be directed from the right and up directions toward the left and down directions of the pixel. Here, the azimuth angle of the pretilt of the first sub-region R1 and the azimuth angle of the pretilt of the third sub-region R3 are opposite to each other, that is, may form 180°, and the azimuth angle of the pretilt of the second sub-region R2 and the azimuth angle of the pretilt of the fourth sub-region R4 are opposite to each other, that is, may form 180°.

Referring to FIG. 3(c), in the first sub-region R1, the upper substrate is light-aligned to have the pretilt, the lower substrate is vertically aligned, and the azimuth angle of the pretilt is aligned to be directed from the right and up directions of the pixel toward the left and down directions, or is aligned to be directed from the left and down directions of the pixel toward the right and up directions, and in the second sub-region R2, the upper substrate is vertically aligned, the lower substrate is light-aligned to have the pretilt, and the pretilt of the azimuth angle is aligned to be directed from the left and up directions of the pixel toward the right and down directions. In the third sub-region R3, the upper substrate is light-aligned to have the pretilt, the lower substrate is vertically aligned, and the azimuth angle of the pretilt is aligned to be directed from the left and down directions of the pixel toward the right and up directions, or is aligned to be directed from the right and up directions of the pixel toward the left and down directions, and in the fourth sub-region R4, the upper substrate is vertically aligned, the lower substrate is light-aligned to have the pretilt, and the azimuth angle of the pretilt is aligned to be directed from the right and down directions of the pixel toward the left and up directions, or is aligned to be directed from the left and up directions toward the right and down directions of the pixel. Here, the azimuth angle of the pretilt of the first sub-region R1 and the azimuth angle of the pretilt of the third sub-region R3 are opposite to each other, that is, may form 180°, and the azimuth angle of the pretilt of the second sub-region R2 and the azimuth angle of the pretilt of the fourth sub-region R4 are opposite to each other, that is, may form 180°.

Referring to FIG. 3(d), in the first sub-region R1, the upper substrate is light-aligned to have the pretilt, the lower substrate is vertically aligned, the azimuth angle of the pretilt is aligned to be directed from the right and up directions of the pixel toward the left and down directions, or is aligned to be directed from the left and down directions of the pixel toward the right and up directions, and in the second sub-region R2, the upper substrate is vertically aligned, the lower substrate is light-aligned to have the pretilt, and the azimuth angle of the pretilt is aligned to be directed from the right and up directions of the pixel toward the left and down directions, or is aligned to be directed from the left and down directions of the pixel toward the right and up directions. In the third sub-region R3, the upper substrate is light-aligned to have the pretilt, the lower substrate is vertically aligned, the azimuth angle of the pretilt is aligned to be directed from the right and down directions of the pixel toward the left and up directions, or is aligned to be directed from the left and up directions of the pixel toward the right and down directions, and in the fourth sub-region R4, the upper substrate is vertically aligned, the lower substrate is light-aligned to have the pretilt, the azimuth angle of the pretilt is aligned to be directed from the right and down directions of the pixel toward the left and up directions, or is aligned to be directed from the left and up directions of the pixel toward the right and down directions.

Referring to FIG. 3(e), in the first sub-region R1, the upper substrate is light-aligned to have the pretilt, the lower substrate is vertically aligned, the azimuth angle of the pretilt is aligned to be directed from the right and up directions of the pixel toward the left and down directions, or is aligned to be directed from the left and down directions of the pixel toward the right and up directions, and in the second sub-region R2, the upper substrate is vertically aligned, the lower substrate is light-aligned to have the pretilt, and the azimuth angle of the pretilt is aligned to be directed from the right and up directions of the pixel toward the left and down directions, or is aligned to be directed from the left and down directions of the pixel toward the right and up directions. In the third sub-region R3, the upper substrate is light-aligned to have the pretilt, the lower substrate is vertically aligned, the azimuth angle of the pretilt is aligned to be directed from the left and down directions of the pixel toward the right and up directions, or is aligned to be directed from the right and up directions of the pixel toward the left and down directions, and in the fourth sub-region R4, the upper substrate is vertically aligned, the lower substrate is light-aligned to have the pretilt, and the azimuth angle of the pretilt is aligned to be directed from the left and down directions of the pixel toward the right and up directions, or is aligned to be directed from the right and up directions of the pixel toward the left and down directions.

As described above, in the manufacturing method of the liquid crystal display according to an exemplary embodiment of the present invention, the pixel including the plurality of regions that are pretilted in the various directions may be formed by using one mask 30. Also, in the manufacturing method of the liquid crystal display according to an exemplary embodiment of the present invention, one of the upper substrate and the lower substrate is light-aligned to have the predetermined azimuth angle and polar angle in each domain, and the other is vertically aligned in the corresponding domain thereby realizing the plurality of domains. Accordingly, compared with the method in which the upper substrate and the lower substrate are light-aligned and the pretilt angle is formed through the vector combination of the upper substrate and the lower substrate, the pretilt direction may be easily controlled, the energy consumed for the alignment is reduced, and the generation of the impurities according to the alignment is reduced.

Referring to FIG. 4, as show in FIG. 4(a) and FIG. 4(b), in the light-alignment method of the liquid crystal display according to the present exemplary embodiment, two mosaic masks 40a and 40b including openings O1 and O2 exposing a portion of a plurality of domains of one pixel and light blocking portions B1 and B2 corresponding to the remaining domains are used to expose the upper substrate and the lower substrate. As described above, two masks 40a and 40b corresponding to one pixel are show in FIG. 4(a) and FIG. 4(b), however a wider region may be simultaneously light-aligned by using a large mask with appropriate openings O1 and O2 repeatedly disposed as one unit (not shown), and the mother substrate may be simultaneously light-aligned by a similar large mask. Also, two masks 40a and 40b corresponding to one pixel are show in FIG. 4(a) and FIG. 4(b), however the positions of the upper substrate and the lower substrate may be reversed after light-aligning one substrate of the upper substrate and the lower substrate by using one of two masks, and the other may be light-aligned. As described above, the azimuth angle that is aligned by controlling the irradiation direction of the ultraviolet rays and exposing two times or more may be controlled to the desired angle.

In the exemplary embodiment shown in FIG. 4, two regions of the pixel are simultaneously light-aligned such that the light-alignment may be faster than in the exemplary embodiment shown in FIG. 3.

FIG. 4(c), FIG. 4(d), and FIG. 4(e) show the light-aligned lower substrate and the light-aligned upper substrate. In FIG. 4(c), FIG. 4(d), and FIG. 4(e), the directions that the liquid crystal directors are directed in the sub-regions R1, R2, R3, and R4 of the pixel are represented by arrows, wherein the case in which the lower substrate is aligned is represented as the solid arrow, and the case in which the upper substrate is aligned is represented as the open lined arrow. The light-aligned pretilt directions shown in FIG. 4(c), FIG. 4(d), and FIG. 4(e) are the same as those of FIG. 3(b), FIG. 3(c), and FIG. 3(e) such that further description thereof is omitted here.

Referring to FIG. 5, in the light-alignment method of the liquid crystal display according to the present exemplary embodiment, as shown in FIG. 5(a), the linearly polarized ultraviolet rays are irradiated to the lower substrate by using a slit mask 50 including an opening O exposing the upper portion of one pixel and a light blocking portion B corresponding to the lower portion thereof for the light-alignment of the lower substrate, and after rotating the mask 50 by 180°, the upper substrate is irradiated with the linearly polarized ultraviolet rays by using the mask 50 for the light-alignment of the upper substrate.

Examples in which the light-aligned lower substrate and the light-aligned upper substrate are combined are shown in FIG. 5(b), FIG. 5(c), and FIG. 5(d). In FIG. 5(b), FIG. 5(c), and FIG. 5(d), the directions that the liquid crystal directors are directed are represented by arrows, wherein the case in which the lower substrate is aligned is represented as the solid arrow, and the case in which the upper substrate is aligned is represented as the open lined arrow. The detailed description is similar to that set forth above with regard to FIG. 3 and FIG. 4, therefore further description is omitted here.

Referring to FIG. 6, in the light-alignment method of the liquid crystal display according to the present exemplary embodiment, as shown in FIG. 6(a) and FIG. 6(b), two masks 60a and 60b corresponding to two pixels are used to expose the upper substrate and the lower substrate. Here, the masks 60a and 60b corresponding to two pixels are shown in FIG. 6(a) and FIG. 6(b), however a wide region may be simultaneously light-aligned by using a large mask with appropriate openings O repeatedly disposed as one unit (not shown), and the mother substrate may be simultaneously light-aligned by a similar large mask. Also, two masks 60a and 60b corresponding to one pixel are shown in FIG. 6(a) and FIG. 6(b), however the positions of the upper substrate and the lower substrate may be reversed up and down after light-aligning one substrate of the upper substrate and the lower substrate by using one of two masks, and then the other may be light-aligned using the same mask. As described above, the azimuth angle that is aligned by controlling the irradiation direction of the ultraviolet rays and exposing two times or more may be controlled to the desired angle.

In the exemplary embodiment shown in FIG. 6, the regions of two pixels are simultaneously light-aligned such that the light-alignment may be faster than in the exemplary embodiment shown in FIG. 5.

FIG. 6(c) shows an example in which the light-aligned lower substrate and the light-aligned upper substrate are combined. In two pixel regions P1 and P2, the directions that the liquid crystal directors are directed are represented by arrows, wherein the case in which the lower substrate is aligned is represented as the solid arrow, and the case in which the upper substrate is aligned is represented as the open lined arrow. Further detailed description is similar to that set forth above with regard to FIG. 3, FIG. 4, and FIG. 5, and is omitted here.

Referring to FIG. 7, in the light-alignment method of the liquid crystal display according to the present exemplary embodiment, the linearly polarized ultraviolet rays are irradiated to the upper substrate and the lower substrate by using the mask 70a shown in FIG. 7(a) and the mask 70b shown in FIG. 7(b) for the light-alignment of the upper substrate and the lower substrate. Here, the light-alignment is executed while sequentially moving the mask such that the entire mother substrate may be light-aligned. The movement of the mask may be executed by the pitch that is two times the interval of the opening O.

Examples in which the light-aligned lower substrate and the light-aligned upper substrate are combined are shown in FIG. 7(c), FIG. 7(d), FIG. 7(e), and FIG. 7(f). In FIG. 7(c), FIG. 7(d), FIG. 7(e), and FIG. 7(f), the directions that the liquid crystal directors are directed are represented by arrows, wherein the case in which the lower substrate is aligned is represented as the solid arrow, and the case in which the upper substrate is aligned is represented as the open lined arrow. Further detailed description is similar to that set forth above and is omitted here.

Referring to FIG. 8, in the light-alignment method of the liquid crystal display according to the present exemplary embodiment, the linearly polarized ultraviolet rays are irradiated to the upper substrate and the lower substrate by using the mask 80 for the light-alignment of the upper substrate and the lower substrate. Here, the light-alignment is executed while sequentially moving the mask such that the entire mother substrate may be light-aligned. The movement of the mask may be executed by a pitch of two times the interval of the opening O. Here, the arrangement of the mask is controlled to light-align one substrate of the upper is substrate and the lower substrate, and to vertically align the other substrate in each sub-region of the pixel.

Examples in which the light-aligned lower substrate and the light-aligned upper substrate are combined are shown in FIG. 8(b), FIG. 8(c), FIG. 8(d), and FIG. 8(e). In FIG. 8(b), FIG. 8(c), FIG. 8(d), and FIG. 8(e), the directions in which the liquid crystal directors are directed are represented by arrows, wherein the case in which the lower substrate is aligned is represented as the solid arrow, and the case in which the upper substrate is aligned is represented as the open lined arrow. Further detailed description is described above and is omitted here.

Referring to FIG. 9, in the light-alignment method of the liquid crystal display according to the present exemplary embodiment, the linearly polarized ultraviolet rays are irradiated to the upper substrate and the lower substrate by using the mask 90a shown in FIG. 9(a) and the mask 90b shown in FIG. 9(b) for the light-alignment of the upper substrate and the lower substrate. The masks 90a and 90b according to the present exemplary embodiment may divide one pixel into at least five sub-regions.

Examples in which the light-aligned lower substrate and the light-aligned upper substrate are combined are shown in FIG. 9(c) and FIG. 9(d). In FIG. 9(c) and FIG. 9(d), the directions that the liquid crystal directors are directed are represented by arrows, wherein the case in which the lower substrate is aligned is represented as the solid arrow, and the case in which the lower substrate is aligned is represented as the open lined arrow. The detailed description is similar to that set forth above and is omitted here. In the present exemplary embodiment, the masks 90a and 90b dividing one pixel into at least five sub-regions are used for the light-alignment such that the pixel may include at least five domains.

Referring to FIG. 10, in the light-alignment method of the liquid crystal display according to the present exemplary embodiment, a mask 100 corresponding to two neighboring pixels is used to respectively expose the upper substrate and the lower substrate, as shown in FIG. 10(a). The position of the other of the upper substrate and the lower substrate may be reversed up and down after light-aligning one substrate of the upper substrate and the lower substrate by using the mask, and the other may be light-aligned. Accordingly, one substrate of the upper substrate and the lower substrate may be only light-aligned in each sub-region of the pixel.

FIG. 10(b) shows the example in which the light-aligned lower substrate and the light-aligned upper substrate are combined. In two pixel regions P1 and P2, the directions that the liquid crystal directors are directed are represented by the arrows, wherein the case in which the lower substrate is aligned is represented as the solid arrow, and the case in which the upper substrate is aligned is represented as the open lined arrow. Further detailed description is omitted.

In the above described exemplary embodiment, the linearly polarized ultraviolet or the partial polarization is irradiated to the alignment layer formed in the upper and lower mother substrates for the light-alignment, however a light-alignment material that tilts about 45° by absorbing a P wave may be used for the light-alignment in another exemplary embodiment of the present invention. In this case, the P wave is emitted by using the light-alignment masks shown in FIG. 3, FIG. 4, FIG. 5, FIG. 6, FIG. 7, FIG. 8, FIG. 9, and FIG. 10 such that the light-alignment of the pretilt having the desired azimuth angle may be realized through only one exposure.

As described above, in the manufacturing method of the liquid crystal display according to an exemplary embodiment of the present invention, the alignment layer formed in one substrate of the lower substrate and the upper substrate is light-aligned per each domain such that the amount of light energy used for the light-alignment may be reduced and control of the alignment direction may be easy, compared with the conventional method in which the alignment layers of the lower substrate and the upper substrate are all light-aligned.

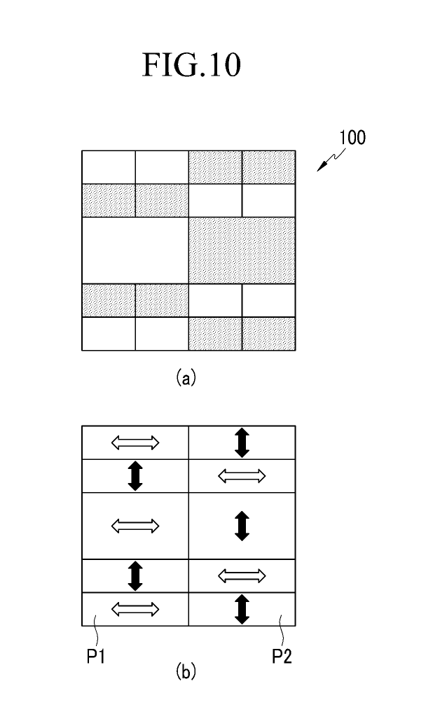

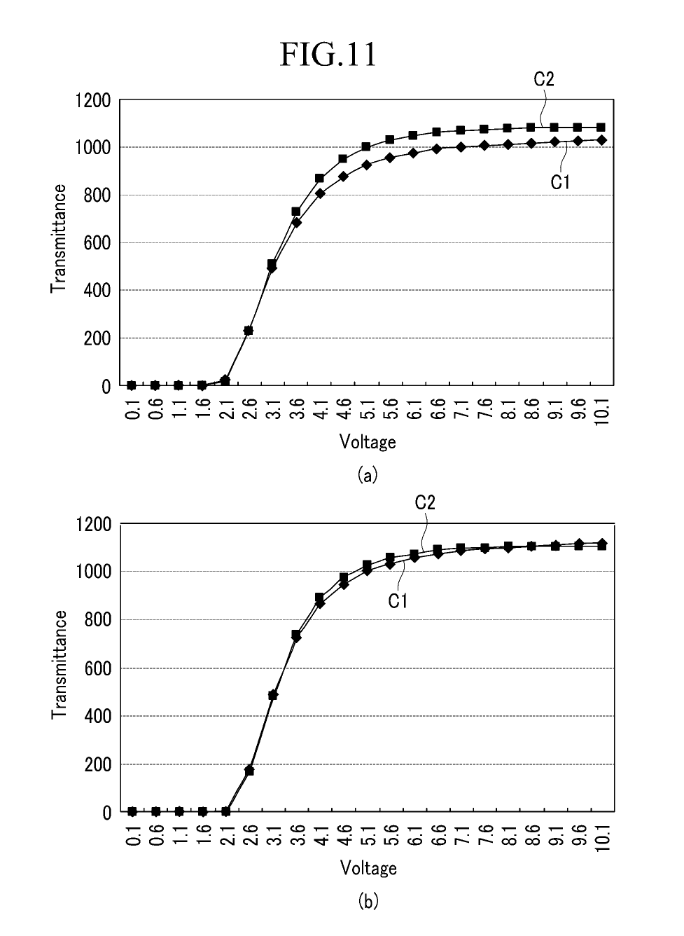

Next, through an experimental example, the performance characteristics of the light-aligned liquid crystal display produced by the manufacturing method of a liquid crystal display according to an exemplary embodiment of the present invention will be described with reference to FIG. 11. FIG. 11 is a graph showing a voltage-transmittance curve according to an experimental example of an exemplary embodiment of the present invention.

In the present experimental examples the same liquid crystal and alignment layer material are used. The first case C1 is one in which the alignment layers of the lower substrate and the upper substrate were light-aligned in directions crossing each other to form the pretilt of the predetermined azimuth angle by the vector combination. The second case C2 is one in which the alignment layer of one of the lower substrate and the upper substrate was pretilted to have the predetermined azimuth angle according to an exemplary embodiment of the present invention. The voltage holding ratio and voltage-transmittance curves were compared. Here, in the second case C2, only the lower substrate is light-aligned, and the upper substrate is vertically aligned. Also, a VA liquid crystal produced by Merck Company is used, and when the direction perpendicular to the surface of the substrate is 0, the linearly polarized ultraviolet rays of 40 degrees are irradiated at an intensity of 50 mJ.

Two experimental examples were executed, wherein the pretilt angle was 88.4° in the first experimental example and the pretilt angle was 89.2° in the second experimental example.

As results, for the first experimental example, the voltage holding ratio of the first case C1 was 98.95% and the voltage holding ratio of the second case C2 was 99.05%, and for the second experimental example, the voltage holding ratio of the first case C1 was 98.99% and the voltage holding ratio of the second case C2 was 99.05%. Compared with the first case C1 that is light-aligned by the conventional method, the second case C2 that is light-aligned by the exemplary embodiment of the present invention has a higher voltage holding ratio.

Next, the transmittance characteristic of the liquid crystal display will be described with reference to FIG. 11. FIG. 11(a) shows the result of the first experimental example, and FIG. 11(b) shows the result of the second experimental example.

Referring to FIG. 11(a), in the first experimental example, compared with the first case C1 that is light-aligned by the conventional method, the second case C2 that is light-aligned by the exemplary embodiment of the present invention has higher transmittance. Referring to FIG. 11(b), in the second experimental example, compared with the first case C1 that is light-aligned by the conventional method, the second case C2 that is light-aligned by the exemplary embodiment of the present invention has higher transmittance.

As described above, the light-aligned liquid crystal display produced through the manufacturing method of the liquid crystal display according to an exemplary embodiment of the present invention has a higher voltage holding ratio and higher transmittance compared with the liquid crystal display formed by the conventional method in which the alignment layers of the lower substrate and the upper substrate are both light-aligned.

Also, as described above, in the manufacturing method of the liquid crystal display according to an exemplary embodiment of the present invention, only the alignment layer disposed on one substrate of the lower substrate and the upper substrate is light-aligned such that only a portion of the lower substrate and the upper substrate is light-aligned. Accordingly, compared with the conventional method in which the alignment layers of the lower substrate and the upper substrate are both light-aligned, the amount of light energy for the light-alignment is reduced, and the control of the alignment direction is easy. Accordingly, the liquid crystal molecules are more easily aligned in the various directions than in the conventional art such that the inclination directions of the liquid crystal molecules are dispersed in the various directions and the response speed of the liquid crystal molecules may be faster.

Accordingly, the liquid crystal display according to an exemplary embodiment of the present invention may easily light-align with less energy in a desired direction, and may reduce impurities resulting from the light-alignment. Accordingly, the inclination direction of the liquid crystal molecules is dispersed in various directions, and the response speed of the liquid crystal may be fast by aligning the liquid crystal molecules in the various directions.

While this invention has been described in connection with what is presently considered to be practical exemplary embodiments, it is to be understood that the invention is not limited to the disclosed embodiments. It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A liquid crystal display, comprising:
a first substrate and a second substrate disposed facing each other; and
a liquid crystal layer disposed between the first substrate and the second substrate and comprising liquid crystal molecules,
wherein the liquid crystal layer comprises a first sub-region and a second sub-region comprising different alignment azimuth angles of the liquid crystal molecules,
the liquid crystal molecules of the first sub-region are aligned to have a first azimuth angle and a polar angle of less than 90° near the first substrate and are vertically aligned near the second substrate, and
the liquid crystal molecules of the second sub-region are aligned to have a second azimuth angle and a polar angle of less than 90° near the second substrate and are vertically aligned near the first substrate.

2. The liquid crystal display of claim 1, wherein
the first azimuth angle of the first sub-region and the second azimuth angle of the second sub-region are disposed 90° to each other.

3. The liquid crystal display of claim 2, wherein
the liquid crystal layer further comprises a third sub-region and a fourth sub-region comprising different alignment azimuth angles of the liquid crystal molecules from the first sub-region and the second sub-region,
the liquid crystal molecules of the third sub-region are aligned to have a third azimuth angle and a polar angle of less than 90° near the first substrate and are vertically aligned near the second substrate,
the liquid crystal molecules of the fourth sub-region are aligned to have a fourth azimuth angle and a polar angle of less than 90° near the second substrate and are vertically aligned near the first substrate,
the first azimuth angle of the first sub-region and the third azimuth angle of the third sub-region are disposed 180° to each other, and
the second azimuth angle of the second sub-region and the fourth azimuth angle of the fourth sub-region are disposed 180° to each other.

4. The liquid crystal display of claim 1, wherein
the first azimuth angle of the first sub-region and the second azimuth angle of the second sub-region are disposed 180° to each other.

5. The liquid crystal display of claim 1, further comprising
a pixel electrode disposed on the second substrate and comprising branches extending in a direction, and
the branches of the pixel electrode disposed in the first sub-region are extended in a direction parallel to the first azimuth angle.

6. The liquid crystal display of claim 1, further comprising
a pixel electrode disposed on the first substrate and comprising branches extending in a direction, and
the branches of the pixel electrode disposed in the second sub-region are extended in a direction parallel to the second azimuth angle.

7. The liquid crystal display of claim 1, further comprising an alignment layer, wherein
the alignment layer comprises a light-polymerized material.

8. The liquid crystal display of claim 7, wherein
the alignment layer further comprises a light stabilizing agent.

9. The liquid crystal display of claim 7, wherein
the alignment layer further comprises a cross-linking agent.

10. A method for manufacturing a liquid crystal display, comprising:
disposing a first mask comprising a first transmission region and a first light blocking region on a first alignment layer disposed on a first substrate;
irradiating ultraviolet rays to the first alignment layer through the first mask to align the first alignment layer corresponding to the first transmission region in a first direction;
disposing a second mask comprising a second transmission region corresponding to the first light blocking region and a second light blocking region corresponding to the first transmission region on a second alignment layer disposed on a second substrate;
irradiating ultraviolet rays to the second alignment layer through the second mask to align the second alignment layer corresponding to the second transmission region in a second direction; and
combining the first substrate and the second substrate such that the first transmission region corresponds to the second light blocking region, and the first light blocking region corresponds to the second transmission region.

11. The method of claim 10, wherein
the first alignment layer and the second alignment layer comprise a light-polymerized material.

12. The method of claim 11, wherein
the first alignment layer and the second alignment layer further comprise a light stabilizing agent.

13. The method of claim 11, wherein
the first alignment layer and the second alignment layer further comprise a cross-linking agent.
